(19) United States
(12) Patent Application Publication
(10) Pub. No.: US 2008/0102622 A1
(43) Pub. Date: May 1, 2008

(54) Method of forming metal line in semiconductor device

(75) Inventors: Jung Geun Kim, Seoul (KR); Cheol Mo Jeong, Kyeongki-do (KR); Whee Won Cho, Chungcheongbuk-do (KR); Seong Hwan Myung, Kyeongki-do (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Kyoungki-do (KR)

(21) Appl. No.: 11/647,088

(22) Filed: Dec. 27, 2006

(30) Foreign Application Priority Data
Oct. 31, 2006 (KR) 2006-106411

(51) Int. Cl. H01L 21/4763

(52) U.S. Cl. 438/618

(57) ABSTRACT

A method of forming a metal line in a semiconductor device, including the steps of forming a metal line in a semiconductor device in which dummy patterns are formed on a dummy region by using non-metal material when a metal line is formed through a damascene process to prevent a formation of an oxide layer on an aluminum layer caused by a slurry and cleaning solution used in the chemical mechanical polishing (CMP) process and carry out an uniform polishing process, whereby it is possible to prevent a digging phenomenon on a metal layer from being generated.

### CROSS-REFERENCE TO RELATED APPLICATION

Priority to Korean patent application number 10-2006-106411 filed Oct. 31, 2006 which is incorporated by reference in its entirety, is hereby claimed.

### BACKGROUND OF THE INVENTION

1. Field of the Invention

The invention relates to a method of forming a metal line in a semiconductor device and, more particularly, to a method of forming a metal line in a semiconductor device utilizing aluminum.

2. Related Technology

As semiconductor devices becomes ultra highly-integrated, minimized in size, and with superior performance, it is necessary to utilize a material for forming a metal line which is advantageous in terms of the RC delay time due to a low specific resistance and excellent resistance against electromigration (EM) and stress migration (SM). Instead of aluminum, which is widely used, copper has been investigated as the most suitable material for the above conditions.

Copper has a relatively high melting point of 1,080° C., while the melting point of aluminum is 660° C., and copper has a specific resistance of 1.7 μΩcm, which is smaller than the specific resistance (2.7 μΩcm) of aluminum, and so copper is utilized as material used for forming a metal line. Due to the excellent properties of copper, an effort has been continued to use copper for the metal line of the semiconductor device. However, copper metal lines have the problems that it is difficult to perform a dry etch to the copper metal line, the copper metal line is easily corroded in an atmosphere, and copper atoms are easily diffused into an insulating layer, and so it is considerably difficult to put the metal line to practical use. A single damascene process or a dual damascene process is utilized for improving the above problems and practically using copper for forming the metal line.

However, since copper has a high diffusion characteristic, an exclusive metal line for copper should be formed by performing separately a copper process and a non-copper process, and so the investment expense becomes increased.

FIG. 1A to FIG. 1C are sectional views of a semiconductor device for illustrating a method of forming a metal line in a semiconductor device according to the prior art.

Referring to FIG. 1A, a semiconductor substrate 100 is etched to form a trench 102 having a certain depth.

Referring to FIG. 1b, an aluminum layer 104 is formed on the entire structure of the semiconductor substrate 100 including the trench 102. Then, a chemical mechanical polishing (CMP) process is performed. At this time, a surface section of the aluminum layer 104 is oxidized to form an aluminum oxide layer 106, this reaction is expressed as follows.

Al (aluminum)+slurry+cleaning solution→aluminum oxide layer

Metal aluminum contained in the aluminum layer 104 is reacted with the slurry and the cleaning solution so that the aluminum oxide layer 106 is formed on a polishing surface. That is, in the chemical mechanical polishing (CMP) process, metal aluminum is not polished, but the aluminum oxide layer 106 is polished as shown in FIG. 1C. At this time, a surface on which the aluminum oxide layer is formed is not uniform, and so the aluminum oxide layer is locally removed in the polishing process and a digging phenomenon on the aluminum oxide layer is generated.

### SUMMARY OF THE INVENTION

The invention solves the aforementioned problems by providing a method of forming a metal wire of a semiconductor device in which dummy patterns are formed on a dummy region by using non-metal material when a metal line is formed through a damascene process using aluminum to prevent a formation of an oxide layer on an aluminum layer caused by a slurry and cleaning solution used in the chemical mechanical polishing (CMP) process and carry out an uniform polishing process, whereby it is possible to prevent a digging phenomenon on a metal layer from being generated.

The method of forming a metal line in a semiconductor device according to one embodiment of the invention includes the steps of forming a damascene pattern and a dummy damascene pattern for forming a metal line on the semiconductor device on which semiconductor elements are formed; filling the damascene pattern with a metal layer; filling the dummy damascene pattern with a non-metal layer; and performing a chemical mechanical polishing process such that electron is transferred from the non-metal layer to the metal layer.

The metal layer is preferably formed of aluminum, and the non-metal layer is preferably formed of any one of zinc (Zn), potassium (K), calcium (Ca), and sodium (Na).

After forming the metal layer and before performing the chemical mechanical polishing process, a sacrificial anode layer is preferably formed on the metal layer for preventing the metal layer from being oxidized. Here, the sacrificial anode layer is preferably a zinc plating layer.

In the chemical mechanical polishing process, (NH₄)₂S₂O₂+H₂O₂ is preferably utilized as a slurry. A cleaning process is preferably performed for removing impurities after performing the chemical mechanical polishing process. In the cleaning process, the electrons existing in the non-metal layer are transferred to cleaning solution and bonded to the elements constituting the cleaning solution or electron of the non-metal layer is transferred to the metal layer so that an oxidation of the metal layer is prevented.

In the chemical mechanical polishing process, a voltage is preferably applied to a pad polishing a wafer and a holder fixing the wafer, so that electrons are supplied to the wafer and oxidation of the metal layer is prevented. Here, the holder is preferably made of a conductive polymer. The voltage preferably is in the range of −5 V to 1.0 V.

### BRIEF DESCRIPTION OF THE DRAWINGS

The above and other objects, features, and advantages of the invention will become apparent from the following description of preferred embodiments given in conjunction with the accompanying drawings, in which:

FIG. 1A to FIG. 1C are sectional views of a semiconductor device for illustrating a method of forming a metal line in a semiconductor device according to the prior art;

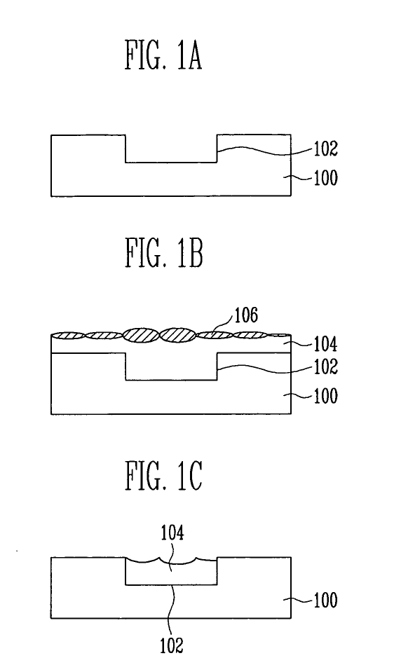

FIG. 2A to FIG. 2C are sectional views of a semiconductor device for illustrating a method of forming a metal line in a semiconductor device according to the invention; and

FIG. 3 is a structural view of a chemical mechanical polishing (CMP) apparatus for illustrating a method of forming a metal line in a semiconductor device according to one embodiment of the invention.

### DESCRIPTION OF SPECIFIC EMBODIMENT

Hereinafter, the preferred embodiment of the invention is described in detail with reference to the accompanying drawings. However, the invention is not limited to the embodiment disclosed below, but can be embodied in the various forms. The embodiment is illustrative, only, and the scope of the invention is defined in the accompanying claims.

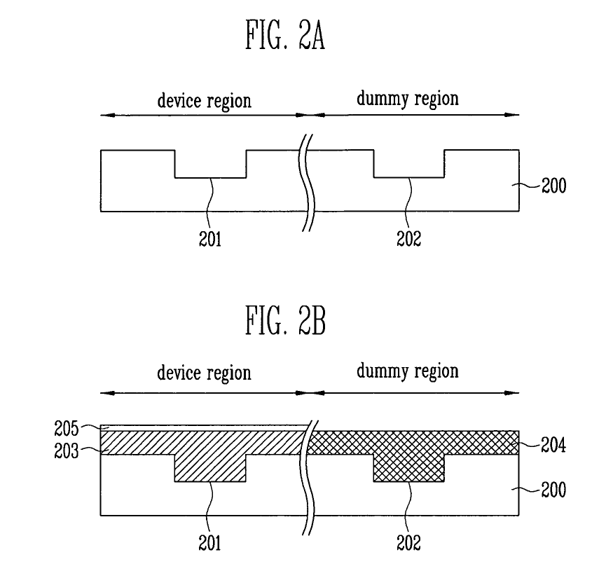

FIG. 2A to FIG. 2C are sectional views of a semiconductor device for illustrating a method of forming a metal line in a semiconductor device according to the invention.

Referring to FIG. 2A, a semiconductor substrate 200 defining a device region and a dummy region is etched to form a damascene pattern 201 on the device region and a dummy damascene pattern 202 on the dummy region.

Referring to FIG. 2B, a metal layer 203 is formed on the device region including the damascene pattern 201, and a non-metal layer 204 is formed on the dummy region including the dummy damascene pattern 202. It is preferred to utilize aluminum for forming the metal layer 203. It is preferred that, after forming the metal layer 203, a sacrificial anode layer 205 is formed in order to prevent a surface of the metal layer 203 from being oxidized. It is desirable to form a zinc plating layer as the sacrifice anode layer 205. It is desirable that the non-metal layer 204 is formed of any one of zinc (Zn), potassium (K), calcium (Ca), or sodium (Na).

Referring to FIG. 2C, a chemical mechanical polishing (CMP) process is carried out such that the metal layer 203 remains in the damascene pattern 201 to form a metal line. At this time, the non-metal layer 204 formed on the dummy region is simultaneously polished. When the chemical mechanical polishing (CMP) process is carried out, since the non-metal layer 204 has a lower electron affinity than aluminum, the electrons existing in the non-metal layer are easily transferred to the polishing etchant and bonded to the elements constituting the polishing etchant. On the other hand, electrons of the non-metal layer which are not bonded with the elements of the polishing etchant are transferred to the metal layer through the polishing etchant, and so the non-metal layer supplies the metal layer 203 with electrons. Accordingly, the non-metal layer prevents the electrons existing in the metal layer 203 from being transferred and bonded to oxygen contained in the polishing etchant, and so oxidation of the metal layer is prevented. It is preferred that (NH₄)₂S₂O₂+H₂O₂ is used as the slurry in the chemical mechanical polishing (CMP) process.

Thereafter, a cleaning process is carried out for removing residue impurities. At this time, the electrons existing in the non-metal layer are transferred to the cleaning solution and bonded to the elements constituting the cleaning solution or electrons of the non-metal layer which are not bonded with the elements of the cleaning solution are transferred to the metal layer 203, and oxidation of the metal layer caused by the cleaning solution is thus prevented. It is preferred that the cleaning process is performed using HF.

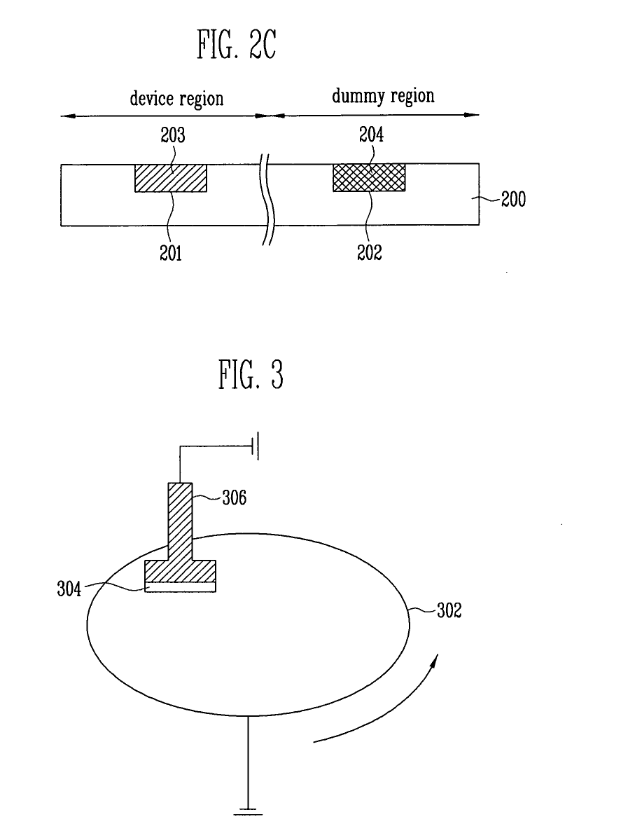

FIG. 3 is a structural view of a chemical mechanical polishing (CMP) apparatus illustrating a method of forming a metal line in a semiconductor device according to one embodiment of the invention.

When the chemical mechanical polishing (CMP) process is performed as shown in FIG. 2C, a voltage is applied to a holder 306 fixing a wafer 304 and a pad 302 which polishes a surface of the wafer 304 as shown in FIG. 3 to supply the wafer 304 with a current. Due to the current supplied to the wafer, it is possible to prevent loss of the electrons existing in the metal layer 203 and the metal layer 203 from being oxidized when the chemical mechanical polishing (CMP) process is performed. At this time, it is preferred that a voltage is −5 V to 1.0 V. Also, the current can be a direct current or an alternating current. In addition, it is preferred that the pad 302 is made of a conductive polymer in order to apply the current to the pad.

As described above, when the chemical mechanical polishing (CMP) process is performing, the non-metal layer 204 formed on a dummy region supplies the metal layer with electrons. Accordingly, formation of an aluminum oxide layer on a surface of the metal layer 203 is prevented, and the degree or mechanical polishing of the non-metal layer is increased relative the degree the chemical polishing. Consequently, it is possible to improve the local digging phenomenon on a surface of the metal layer 203.

According to one embodiment of the invention, when the metal line is formed through the damascene process using aluminum, dummy patterns are formed on the dummy region by using non-metallic material, and so formation of the oxide layer on the aluminum layer caused by the slurry and the cleaning solution used in the chemical mechanical polishing (CMP) process is prevented and the uniform polishing process is performed to prevent the digging phenomenon on the metal layer from being generated.

Although the technical spirit of the invention has been concretely described in connection with the preferred embodiment, the scope of the invention is not limited by the specific embodiments but should be construed by the appended claims. Further, those skilled in the art will understand that various changes and modifications can be made thereto without departing from the scope of the invention.

What is claimed is:

1. A method of forming a metal line in a semiconductor device, comprising the steps of;
forming a damascene pattern and a dummy damascene pattern for forming a metal line on the semiconductor device on which semiconductor elements are formed;
filling the damascene pattern with a metal layer;
filling the dummy damascene pattern with a non-metal layer; and
performing a chemical mechanical polishing process such that electrons are transferred from the non-metal layer to the metal layer.

2. The method of forming the metal line in the semiconductor device as claimed in claim 1, wherein the metal layer is formed of aluminum.

3. The method of forming the metal line in the semiconductor device as claimed in claim 1, wherein the non-metal layer is formed of any one of zinc (Zn), potassium (K), calcium (Ca), and sodium (Na).

4. The method of forming the metal line in the semiconductor device as claimed in claim 1, further comprising the step of forming a sacrificial anode layer on the metal layer for preventing the metal layer from being oxidized after forming the metal layer and before performing the chemical mechanical polishing process.

5. The method of forming the metal line in the semiconductor device as claimed in claim 4, wherein the sacrificial anode layer is a zinc plating layer.

6. The method of forming the metal line in the semiconductor device as claimed in claim 1, wherein the chemical mechanical polishing process utilizes (NH₄)₂S₂O₂+H₂O₂ as a slurry.

7. The method of forming the metal line in the semiconductor device as claimed in claim 1, further comprising the step of cleaning the metal layer to remove impurities after performing the chemical mechanical polishing process.

8. The method of forming the metal line in the semiconductor device as claimed in claim 7, wherein, in the cleaning process, the electrons existing in the non-metal layer are transferred to a cleaning solution and bonded to elements or the cleaning solution or electrons of the non-metal layer are transferred to the metal layer, whereby oxidation of the metal layer is prevented.

9. The method of forming the metal line in the semiconductor device as claimed in claim 1, wherein the chemical mechanical polishing process includes the step of applying a voltage to a pad and a holder to supply the wafer with electron and prevent the metal layer from being oxidized.

10. The method of forming the metal line in the semiconductor device as claimed in claim 9, wherein the holder is made of conductive polymer.

11. The method of forming the metal line in the semiconductor device as claimed in claim 9, wherein the voltage is in the range of −5 V to 1.0 V.
